(19) United States
(12) Patent Application Publication
(10) Pub. No.: US 2009/0096012 A1
(43) Pub. Date: Apr. 16, 2009

(54) FLASH MEMORY DEVICE AND METHOD OF FABRICATING THE SAME

(75) Inventor: Kwang Chul JOO, Yongin-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 12/163,489

(22) Filed: Jun. 27, 2008

(30) Foreign Application Priority Data
Oct. 10, 2007 (KR) 2007-102129

(51) Int. Cl. H01L 29/788; H01L 21/28

(52) U.S. Cl. 257/321; 438/591; 257/E29.3; 257/E21.179

(57) ABSTRACT

A flash memory secures a desired coupling ratio in a target thickness by lowering the leakage current through a high-dielectric (k) layer employing a combination of energy band gaps. The flash memory device includes a tunnel insulating layer formed on a semiconductor substrate, a first conductive layer formed on the tunnel insulating layer, a high-dielectric (k) layer having a stacked structure of first, second and third high-k insulating layers formed on the first conductive layer, and a second conductive layer formed on the high-k layer. The first high-k insulating layer has a first energy bandgap, the second high-k insulating layer has a second energy bandgap greater than the first energy bandgap, and the third high-k insulating layer has a third energy bandgap smaller than the second energy bandgap.

### CROSS-REFERENCES TO RELATED APPLICATIONS

The present application claims priority to Korean patent application number 10-2007-0102129, filed on Oct. 10, 2007, which is incorporated by reference in its entirety.

### BACKGROUND OF THE INVENTION

The present invention relates to a flash memory device and a method of fabricating the same and, more particularly, to a flash memory device and a method of fabricating the same, which can secure a desired coupling ratio in a target thickness by lowering the leakage current through a high-dielectric (k) layer employing a combination of energy bandgaps.

In general, a non-volatile memory device retains data when power is off. A unit cell of the non-volatile memory device has a structure in which a tunnel insulating layer, a floating gate, a dielectric layer and a control gate are sequentially stacked over an active region of a semiconductor substrate. External voltage applied to a control gate electrode is coupled to the floating gate, and data is stored in the unit cell. Thus, if it is sought to store data in short bursts and at a low program voltage, the ratio of voltage applied to the control gate electrode versus voltage induced in the floating gate must be large. The ratio of voltage applied to the control gate electrode to voltage induced in the floating gate is called a coupling ratio. The coupling ratio can also be represented as the ratio of capacitance of a gate pre-metal dielectric layer with the sum of capacitance of the tunnel insulating layer and the gate pre-metal dielectric layer.

Recently, as devices become more highly integrated, the cell size is decreased and the capacitance of a dielectric layer is reduced. Thus, an existing dielectric layer structure of an oxide layer, a nitride layer and an oxide layer (ONO), which is fabricated using a chemical vapor deposition (CVD) having a step coverage of about 85%, may not meet coupling ratio and leakage current specifications. Therefore, in order to secure a desired coupling ratio, the thickness of the dielectric layer is reduced. However, if the thickness of the dielectric layer is decreased, the leakage current is increased and the charge retention characteristic is degraded, resulting in degraded characteristics of the device.

To solve the above problems, active research has recently been conducted to develop a dielectric layer employing a high-k material to replace an existing dielectric layer. However, if a dielectric layer is formed using only a high-k material, the charge retention characteristic cannot be met because of a high leakage current. In order to supplement the shortcomings of the high-k material by improving the high leakage current characteristic of the dielectric layer, a low-k material (for example, a silicon oxide (SiO₂) layer) is stacked on and below a high-k insulating layer employing a high-k material. In this case, the dielectric constant of the dielectric layer is lowered due to the upper and lower silicon oxide layers, so the equivalent oxide thickness (EOT) is increased and the physical thickness of the dielectric layer is increased. Thus, if the sidewalls of a floating gate between cells of an integrated device are gap-filled, a polysilicon layer or a metal layer for a control gate cannot be gap-filled between the floating gates. Consequently, the capacitance is decreased and a coupling ratio necessary for the operation of the device cannot be secured, thereby failing in performance as an electrode.

### BRIEF SUMMARY OF THE INVENTION

The present invention is directed towards a flash memory device and a method of fabricating the same, which can increase a tunneling distance of a leakage current to lower the leakage current by forming a high-k layer employing a combination of energy band gaps of a high-k material. Thus, the EOT and the physical thickness can meet a target thickness and secure a coupling ratio necessary for the operation of a device.

A flash memory device in accordance with an aspect of the present invention includes a tunnel insulating layer formed on a semiconductor substrate, a first conductive layer formed on the tunnel insulating layer, a high-dielectric (k) layer having a stack structure of first, second and third high-k insulating layers formed on the first conductive layer, and a second conductive layer formed on the high-k layer. The first high-k insulating layer may have a first energy bandgap, the second high-k insulating layer may have a second energy bandgap greater than the first energy bandgap, and the third high-k insulating layer may have a third energy bandgap smaller than the second energy bandgap.

The first energy bandgap may be identical to the third energy bandgap. The first high-k insulating layer and the third high-k insulating layer are formed using the same material. Each of the first and third high-k insulating layers can be formed using any one of HfO₂, ZrO₂, TiO₂ and SrTiO₃. The second high-k insulating layer can be formed using any one of HfO₂, ZrO₂, TiO₂ and Al₂O₃.

The first conductive layer may be formed from a doped polysilicon layer. The second conductive layer may be formed of a doped polysilicon layer, a metal layer, or a stack layer of the doped polysilicon layer and the metal layer. The metal layer may be formed using any one of TiN, TaN, W, WN, WSi, Ru, RuO₂, Ir, IrO₂ and Pt.

A first nitrogen-containing insulating layer may be formed between the first conductive layer and the first high-k insulating layer. The first nitrogen-containing insulating layer may be formed of a silicon nitride (Si₃N₄) layer. A second nitrogen-containing insulating layer may be formed between the third high-k insulating layer and the second conductive layer.

A method of fabricating a flash memory device in accordance with another aspect of the present invention includes providing a semiconductor substrate over which a tunnel insulating layer and a first conductive layer are formed, forming a high-k layer by sequentially stacking a first high-k insulating layer, a second high-k insulating layer, and a third high-k insulating layer over the first conductive layer, and forming a second conductive layer on the high-k layer. The first high-k insulating layer may have a first energy bandgap, the second high-k insulating layer may have a second energy bandgap greater than the first energy bandgap, and the third high-k insulating layer may have a third energy bandgap smaller than the second energy bandgap.

The first energy bandgap may be identical to the third energy bandgap. The first high-k insulating layer and the third high-k insulating layer are formed using the same material. Each of the first and third high-k insulating layers may be formed using any one of HfO₂, ZrO₂, TiO₂ and SrTiO₃. The second high-k insulating layer may be formed using any one of HfO₂, ZrO₂, TiO₂ and Al₂O₃.

The first conductive layer may be formed from a doped polysilicon layer. The second conductive layer may be formed of a doped polysilicon layer, a metal layer, or a stacked layer of the doped polysilicon layer and the metal layer. The metal layer may be formed using any one of TiN, TaN, W, WN, WSi, Ru, RuO₂, Ir, IrO₂ and Pt.

A first nitrogen-containing insulating layer is formed between the first conductive layer and the first high-k insulating layer. The first nitrogen-containing insulating layer may be formed of a silicon nitride (Si₃N₄) layer. A second nitrogen-containing insulating layer is formed between the third high-k insulating layer and the second conductive layer.

The first nitrogen-containing insulating layer may be formed using any one of a plasma nitrification (PN) treatment process, a furnace annealing process and a rapid thermal process (RTP). The PN treatment process may be performed in a temperature range of 300 to 800 degrees Celsius under a pressure of 0.1 to 10 torr using power of 5 kW and below. The PN treatment process may be performed using N₂, N₂O or NO gas. The furnace annealing process may be performed using NH₃ gas in a temperature range of 600 to 900 degrees Celsius. The RTP may be performed using NH₃ gas in a temperature range of 600 to 1000 degrees Celsius.

### BRIEF DESCRIPTION OF THE DRAWINGS

FIGS. 1A to 1H are sectional views sequentially illustrating a method of fabricating a flash memory device in accordance with an embodiment of the present invention; and

FIG. 2 is a diagram showing the energy bandgaps of a high-k layer in accordance with an embodiment of the present invention.

### DESCRIPTION OF SPECIFIC EMBODIMENTS

Specific embodiments according to the present invention will be described with reference to the accompanying drawings. However, the present invention is not limited to the disclosed embodiments, but may be implemented in various manners. The embodiments are provided to complete the disclosure of the present invention and to allow those having ordinary skill in the art to understand the present invention. The present invention is defined by the scope of the claims.

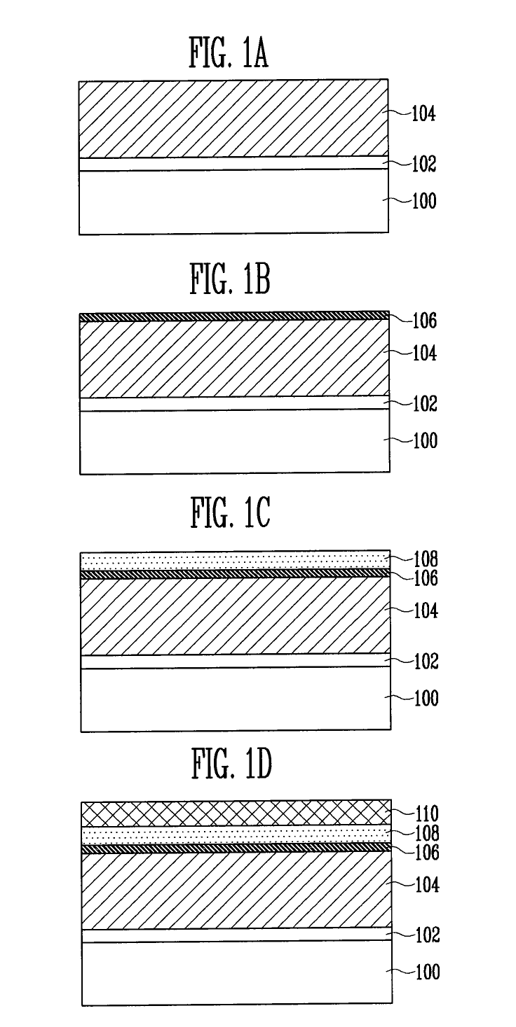

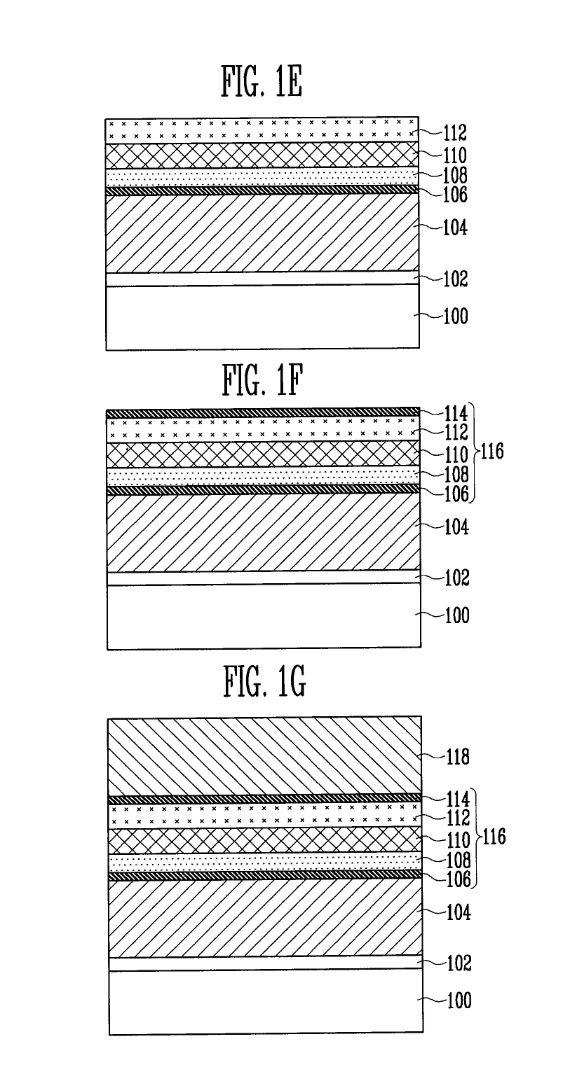

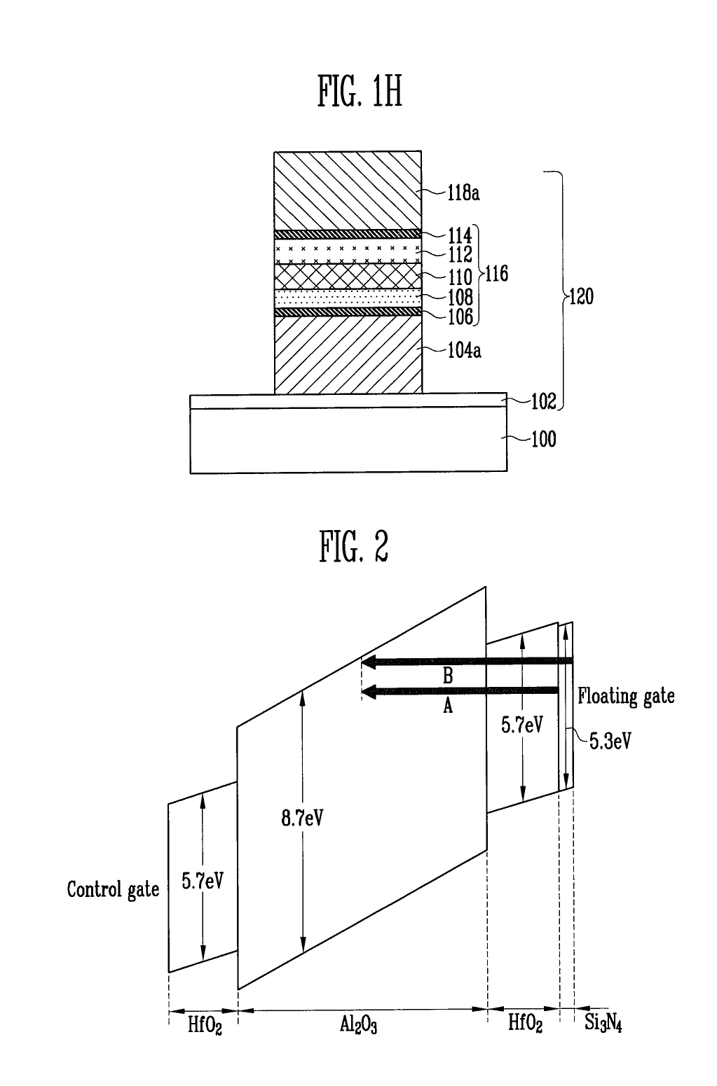

FIGS. 1A to 1H are sectional views sequentially illustrating a method of fabricating a flash memory device in accordance with an embodiment of the present invention

Referring to FIG. 1A, a semiconductor substrate 100 in which a well area (not shown) is formed is provided. The well area can have a triple structure. The well area is formed by forming a screen oxide layer (not shown) over the semiconductor substrate 100 and then performing a well ion implantation process and a threshold voltage ion implantation process.

After the screen oxide layer is removed, a tunnel insulating layer 102 is formed on the semiconductor substrate 100 having the well area formed therein. The tunnel insulating layer 102 can be formed of a silicon oxide (SiO₂) layer. The tunnel insulating layer 102 can be formed using an oxidation process.

A first conductive layer 104 is formed on the tunnel insulating layer 102. The first conductive layer 104 is for forming a floating gate of the flash memory device and can be formed of a doped polysilicon layer.

The first conductive layer 104 is patterned in one direction (a bit line direction) using an etch process employing a mask (not shown). After an exposed tunnel insulating layer 102 is etched, the semiconductor substrate 100, which is exposed due to the exposure of the tunnel insulating layer 102, is etched, thereby forming trenches (not shown) in an isolation area. An insulating material is deposited on the first conductive layer 104, including the trenches, so that the trenches are gap-filled. The deposited insulating material is polished to form isolation layers (not shown) within the trenches. A photoresist pattern can be used as a mask. The photoresist pattern can be formed by coating a photoresist on the first conductive layer 104 and patterning the photoresist using exposure and development processes.

Referring to FIG. 1B, a first nitrogen-containing insulating layer 106 is formed on the patterned first conductive layer 104 and the isolation layers (not shown). The first nitrogen-containing insulating layer 106 prevents a silicate layer from being formed on a surface of the first conductive layer 104 due to an interface reaction of the first conductive layer 104 made of the polysilicon layer and a subsequent lower layer of a high-k layer made of a high-k material when the lower layer of the high-k layer is formed over the first conductive layer 104. The first nitrogen-containing insulating layer 106 can be formed of a silicon nitride (Si₃N₄) layer having a relatively low energy bandgap of 5.3 eV.

The silicon nitride (Si₃N₄) layer can be formed using any one of a plasma nitrification (PN) treatment process, a furnace annealing process and a rapid treatment process (RTP). More specifically, the PN treatment process can be performed using N₂, N₂O or NO gas in a temperature range of 300 to 800 degrees Celsius under a pressure of 0.1 to 10 torr using power of 0 kW to 5 kW. The furnace annealing process can be performed using NH₃ gas in a temperature range of 600 to 900 degrees Celsius. The RTP process can be performed using NH₃ gas in a temperature range of 600 to 1000 degrees Celsius. Accordingly, a surface of the first conductive layer 104, which is comprised of the polysilicon layer, is nitrified, thereby forming the first nitrogen-containing insulating layer 106 made of the silicon nitride (Si₃N₄) layer.

When the first nitrogen-containing insulating layer 106 comprised of the silicon nitride (Si₃N₄) layer is formed on the first conductive layer 104 as described above, the silicate layer can be prevented from being formed on the first conductive layer 104. In general, the silicate layer is a low-k material having a high energy bandgap of 8.9 eV and shortens the tunneling distance of the leakage current. Therefore, the silicate layer increases not only the leakage current, but also the EOT and the physical thickness. However, the silicon nitride (Si₃N₄) layer has a relatively low energy bandgap of 5.3 eV and therefore increases the tunneling distance of the leakage current and lowers the leakage current.

When the first nitrogen-containing insulating layer 106 is formed, in a positive bias, surface roughness of the first conductive layer 104 is improved to increase a breakdown voltage. In a negative bias, the concentration of oxygen vacancy is lowered due to high oxidization resistance of the first nitrogen-containing insulating layer 106 to decrease the number of electrons trapped at the first conductive layer 104 and to prevent an abrupt increase of a gate voltage.

Referring to FIG. 1C, a first high-k insulating layer 108 is formed on the first nitrogen-containing insulating layer 106. The first high-k insulating layer 108 is formed as a lower layer of the high-k layer of the flash memory device and is formed of a high-k material having a first energy bandgap.

In general, the energy bandgaps of the high-k material have HfO₂—5.7 eV, ZrO₂—5.6 eV, TiO₂—3.5 eV, SrTiO₃—3.3 eV and Al₂O₃—8.7 eV. Thus, the first high-k insulating layer 108 can be formed using any one of HfO₂, ZrO₂, TiO₂ and SrTiO₃, which have a relatively low energy bandgap. In particular, since material having a low energy bandgap has a high dielectric constant, it is preferred that the first high-k insulating layer 108 be formed using material having a relatively low energy bandgap to lower the EOT and the physical thickness.

Referring to FIG. 1D, a second high-k insulating layer 110 is formed on the first high-k insulating layer 108. The second high-k insulating layer 110 is used as an intermediate layer of the high-k layer of the flash memory device. The second high-k insulating layer 110 is formed from a high-k material having a second energy bandgap greater than the first energy bandgap of the first high-k insulating layer 108. The second high-k insulating layer 110 may be formed using any one of HfO₂, ZrO₂, TiO₂ and Al₂O₃.

Referring to FIG. 1E, a third high-k insulating layer 112 is formed on the second high-k insulating layer 110. The third high-k insulating layer 112 is used as an upper layer of the high-k layer of the flash memory device. The third high-k insulating layer 112 is formed from a high-k material having a third energy bandgap smaller than the second energy bandgap of the second high-k insulating layer 110.

The first energy bandgap of the first high-k insulating layer 108 may be identical to the third energy bandgap of the third high-k insulating layer 112. The first high-k insulating layer 108 and the third high-k insulating layer 112 may be formed using the same material. The third high-k insulating layer 112 may be formed using any one of HfO₂, ZrO₂, TiO₂ and SrTiO₃ having a low energy bandgap.

Referring to FIG. 1F, a second nitrogen-containing insulating layer 114 is formed on the third high-k insulating layer 112. The second nitrogen-containing insulating layer 114 prevents a silicate layer from being formed on a surface of the third high-k insulating layer 112 due to an interfacial reaction of the third high-k insulating layer 112 and a subsequent polysilicon layer for a control gate when the conductive layer for the control gate is formed of a polysilicon layer. The second nitrogen-containing insulating layer 114 may be formed using any one of a PN treatment process, a furnace annealing process and a RTP.

The plasma nitrification treatment process may be performed using N₂, N₂O or NO gas in a temperature range of 300 to 800 degrees Celsius under a pressure of 0.1 to 10 torr using power of 0 kW to 5 kW. The furnace annealing process may be performed using NH₃ gas in a temperature range of 600 to 900 degrees Celsius. The RTP process may be performed using NH₃ gas in a temperature range of 600 to 1000 degrees Celsius. Accordingly, a surface of the third high-k insulating layer 112 is nitrified, thereby forming the second nitrogen-containing insulating layer 114.

The second nitrogen-containing insulating layer 114 may be omitted when the conductive layer for the control gate is not formed from the polysilicon layer.

If the second nitrogen-containing insulating layer 114 is formed on the third high-k insulating layer 112 as described above, a silicate layer is prevented from being formed on the third conductive layer 112. Thus, an increase of the EOT and the physical thickness of a subsequent high-k layer is prevented from increasing.

The first nitrogen-containing insulating layer 106, the first high-k insulating layer 108, the second high-k insulating layer 110, the third high-k insulating layer 112, and the second nitrogen-containing insulating layer 114 constitute a high-k layer 116.

As described above, a relative energy bandgap between the first, second and third high-k insulating layers 108, 110 and 112, constituting the high-k layer 116 according to an embodiment of the present invention, has a combination of a low energy bandgap (low)-a high energy bandgap (high)-a low energy bandgap (low). Accordingly, the tunneling distance of the leakage current can be increased and the leakage current can be lowered.

Further, when the high-k layer 116 has the relative energy bandgap of the combination of low-high-low, the high-k layer 116 with an improved leakage current characteristic can be formed using a high-k material without using a low-k material. Therefore, the leakage current characteristic can be secured and the EOT and physical thickness can be lowered to meet a target thickness, when compared with using a low-k layer.

Referring to FIG. 1G, a second conductive layer 118 is formed on the second nitrogen-containing insulating layer 114 of the high-k layer 116. The second conductive layer 118 is for forming the control gate of the flash memory device. The second conductive layer 118 may be formed of a doped polysilicon layer, a metal layer or a stacked layer of a doped polysilicon layer and a metal layer. The metal layer may be formed using any one of TiN, TaN, W, WN, WSi, Ru, RuO₂, Ir, IrO₂ and Pt.

A hard mask layer (not shown) may be further formed on the second conductive layer 118 to prevent the second conductive layer 118 from being damaged in a subsequent gate etch process.

Referring to FIG. 1H, a typical etch process is performed to sequentially pattern the hard mask layer, the second conductive layer 118, the high-k layer 116, and the first conductive layer 104. The patterning process is performed in a direction to cross the first conductive layer 104 (a word line direction), which is patterned in one direction (a bit line direction).

Accordingly, a floating gate 104a comprised of the first conductive layer 104 and a control gate 118a comprised of the second conductive layer 118 are formed. The tunnel insulating layer 102, the floating gate 104a, the high-k layer 116, the control gate 118a, and the hard mask layer constitute a gate pattern 120.

FIG. 2 is a diagram showing the energy bandgaps of the high-k layer in accordance with an embodiment of the present invention.

FIG. 2 illustrates a high-k layer having a HfO₂ (5.7 eV)/Al₂O₃ (8.7 eV)/HfO₂ (5.7 eV) stacked layer with relative energy bandgaps of a combination of low-high-low, which is formed between the floating gate and the control gate employing high-k materials, including HfO₂ having an energy band gap of 5.7 eV and Al₂O₃ having an energy bandgap of 8.7 eV according to the fabrication method of FIGS. 1A to 1G. The leakage current can be lowered by increasing the tunneling distance (or the leakage path distance) of the leakage current to ‘A’ to improve the leakage current characteristic.

If a silicon nitride (Si₃N₄) layer is further formed on the floating gate, a silicate layer with a high energy bandgap is prevented from being formed on a surface of the floating gate, and the tunneling distance of the leakage current may be increased from ‘A’ to ‘B’ through the silicon nitride (Si₃N₄) layer with a low energy bandgap (−5.3 eV). Accordingly, the leakage current may be further lowered and the leakage current characteristic may be further improved.

In the present invention, the high-k layer having the combination of low-high-low has been described as the stacked layer of HfO₂/Al₂O₃/HfO₂, for convenience of description. However, it is to be understood that a variety of high-k layers having a combination of low-high-low, such as ZrO₂ (5.6 eV)/HfO₂ (5.7 eV)/ZrO₂ (5.6 eV) or ZrO₂ (5.6 eV)/Al₂O₃ (8.7 eV)/ZrO₂ (5.6 eV), may be formed by properly combining materials selected from HfO₂, ZrO₂, TiO₂, SrTiO₃ and Al₂O₃. Accordingly, the tunneling distance of the leakage current may be increased and the leakage current may be lowered.

As described above, the present invention exhibits the following advantages.

First, the high-k layer is formed from high-k materials such that the energy bandgaps become low-high-low. Accordingly, the tunneling distance of the leakage current may be increased and the leakage current may be lowered.

Second, since the leakage current characteristic of the high-k layer is improved, capacitance between the floating gate and the control gate is increased while the EOT and the physical thickness of the high-k layer meet a target thickness. Accordingly, a coupling ratio necessary for the operation of a device is secured.

Third, the silicon nitride (Si₃N₄) layer with a low energy bandgap is formed on the polysilicon layer for the floating gate to prohibit a silicate layer from being formed at the interface of the polysilicon layer for the floating gate and the lower layer of the high-k layer. Accordingly, the tunneling distance of the leakage current is further extended through the silicon nitride (Si₃N₄) layer with a low energy bandgap. Consequently, the leakage current may be further lowered.

Fourth, when the silicon nitride (Si₃N₄) layer is formed on the polysilicon layer for the floating gate, surface roughness of the polysilicon layer is improved to increase a breakdown voltage. Further, the concentration of oxygen vacancy of the polysilicon layer may be lowered to decrease the number of electrons trapped at the polysilicon layer. Therefore, an abrupt increase of a gate voltage may be prevented.

Fifth, the nitrogen-containing insulating layer is formed between the upper layer of the high-k layer and the polysilicon layer for the control gate to prevent a silicate layer from being formed at the interface therebetween. Accordingly, an increase of the EOT and the physical thickness may be prevented.

The embodiments disclosed herein have been proposed to allow a person skilled in the art to easily implement the present invention, and the person skilled in the part may implement the present invention by a combination of these embodiments. Therefore, the scope of the present invention is not limited by or to the embodiments as described above, and should be construed to be defined only by the appended claims and their equivalents.

What is claimed is:

1. A flash memory device, comprising:
a tunnel insulating layer formed over a semiconductor substrate;
a first conductive layer formed over the tunnel insulating layer;
a high-dielectric (k) layer comprising a stacked structure of a first high-k insulating layer, a second high-k insulating layer, and a third high-k insulating layer formed over the first conductive layer, wherein the first high-k insulating layer has a first energy bandgap, the second high-k insulating layer has a second energy bandgap greater than the first energy bandgap, and the third high-k insulating layer has a third energy bandgap smaller than the second energy bandgap; and
a second conductive layer formed over the high-k layer.

2. The flash memory device of claim 1, wherein the first energy bandgap is substantially identical to the third energy bandgap.

3. The flash memory device of claim 1, wherein the first high-k insulating layer and the third high-k insulating layer are formed using the same material.

4. The flash memory device of claim 1, wherein each of the first and third high-k insulating layers is formed using any one of HfO₂, ZrO₂, TiO₂ and SrTiO₃.

5. The flash memory device of claim 1, wherein the second high-k insulating layer is formed using any one of HfO₂, ZrO₂, TiO₂ and Al₂O₃.

6. The flash memory device of claim 1, wherein the first conductive layer is formed of a doped polysilicon layer.

7. The flash memory device of claim 1, wherein the second conductive layer is formed of a doped polysilicon layer, a metal layer, or a stacked layer of the doped polysilicon layer and the metal layer.

8. The flash memory device of claim 7, wherein the metal layer is formed using any one of TiN, TaN, W, WN, WSi, Ru, RuO₂, Ir, IrO₂ and Pt.

9. The flash memory device of claim 1, wherein a first nitrogen-containing insulating layer is formed between the first conductive layer and the first high-k insulating layer.

10. The flash memory device of claim 9, wherein the first nitrogen-containing insulating layer is formed of a silicon nitride (Si₃N₄) layer.

11. The flash memory device of claim 1, wherein a second nitrogen-containing insulating layer is formed between the third high-k insulating layer and the second conductive layer.

12. A method of fabricating a flash memory device, comprising:
providing a semiconductor substrate over which a tunnel insulating layer and a first conductive layer are formed;
forming a high-k layer by sequentially stacking a first high-k insulating layer, a second high-k insulating layer, and a third high-k insulating layer over the first conductive layer, wherein the first high-k insulating layer has a first energy bandgap, the second high-k insulating layer has a second energy bandgap greater than the first energy bandgap, and the third high-k insulating layer has a third energy bandgap smaller than the second energy bandgap; and
forming a second conductive layer over the high-k layer.

13. The method of claim 12, wherein the first energy bandgap is substantially identical to the third energy band gap.

14. The method of claim 12, wherein the first high-k insulating layer and the third high-k insulating layer are formed using the same material.

15. The method of claim 12, wherein each of the first and third high-k insulating layers is formed using any one of HfO₂, ZrO₂, TiO₂ and SrTiO₃.

16. The method of claim 12, wherein the second high-k insulating layer is formed using any one of HfO₂, ZrO₂, TiO₂ and Al₂O₃.

17. The method of claim 12, wherein the first conductive layer is formed of a doped polysilicon layer.

18. The method of claim 12, wherein the second conductive layer is formed of a doped polysilicon layer, a metal layer, or a stacked layer of the doped polysilicon layer and the metal layer.

19. The method of claim 18, wherein the metal layer is formed using any one of TiN, TaN, W, WN, WSi, Ru, RuO₂, Ir, IrO₂ and Pt.

20. The method of claim 12, further comprising forming a first nitrogen-containing insulating layer between the first conductive layer and the first high-k insulating layer.

21. The method of claim 20, wherein the first nitrogen-containing insulating layer is formed of a silicon nitride (Si₃N₄) layer.

22. The method of claim 20, wherein the first nitrogen-containing insulating layer is formed using any one of a plasma nitrification (PN) treatment process, a furnace annealing process and a rapid thermal process (RTP).

23. The method of claim 22, wherein the PN treatment process is performed in a temperature range of 300 to 800 degrees Celsius under a pressure of 0.1 to 10 torr using power of 5 kW and below.

24. The method of claim 22, wherein the PN treatment process is performed using N₂, N₂O or NO gas.

25. The method of claim 22, wherein the furnace annealing process is performed using NH₃ gas in a temperature range of 600 to 900 degrees Celsius.

26. The method of claim 22, wherein the RTP is performed using NH₃ gas in a temperature range of 600 to 1000 degrees Celsius.

27. The method of claim 12, further comprising forming a second nitrogen-containing insulating layer between the third high-k insulating layer and the second conductive layer.

28. The method of claim 27, wherein the second nitrogen-containing insulating layer is formed using any one of a PN treatment process, a furnace annealing process and a RTP.

29. The method of claim 28, wherein the PN treatment process is performed in a temperature range of 300 to 800 degrees Celsius under a pressure of 0.1 to 10 torr using power of 5 kW and below.

30. The method of claim 28, wherein the PN treatment process is performed using N₂, N₂O or NO gas.

31. The method of claim 28, wherein the furnace annealing process is performed using NH₃ gas in a temperature range of 600 to 900 degrees Celsius.

32. The method of claim 28, wherein the RTP is performed using NH₃ gas in a temperature range of 600 to 1000 degrees Celsius.
